(19) United States
(12) Patent Application Publication
(10) Pub. No.: US 2026/0122912 A1
(43) Pub. Date: Apr. 30, 2026

(54) MAGNETORESISTIVE RANDOM ACCESS MEMORY AND METHOD FOR FABRICATING THE SAME

(71) Applicant: UNITED MICROELECTRONICS CORP., Hsin-Chu City (TW)

(72) Inventors: Hui-Lin Wang, Taipei City (TW); I-Fan Chang, Tainan City (TW); Yi-An Huang, New Taipei City (TW); Rai-Min Huang, Taipei City (TW); Chen-Yi Weng, New Taipei City (TW); Po-Kai Hsu, Tainan City (TW); Hung-Yueh Chen, Hsinchu City (TW)

(73) Assignee: UNITED MICROELECTRONICS CORP., Hsin Chu City (TW)

(21) Appl. No.: 18/964,703

(22) Filed: Dec. 2, 2024

(30) Foreign Application Priority Data
Oct. 28, 2024 (TW) 113141037

(51) Int. Cl. H10B 61/00; H10N 50/01; H10N 50/10

(52) U.S. Cl. CPC H10B 61/10; H10N 50/01; H10N 50/10

(57) ABSTRACT

A method for fabricating a magnetoresistive random access memory (MRAM) device includes the steps of providing a substrate having a MRAM region and a logic region, forming a first inter-metal dielectric (IMD) layer on the substrate, forming a metal nitride layer on the first IMD layer, using a first patterned mask to remove the metal nitride layer on the logic region, using a second patterned mask to remove the metal nitride layer on the MRAM region, using a third patterned mask to remove the first IMD layer on the MRAM region and the logic region, forming a first metal interconnection on the MRAM region and a second metal interconnection on the logic region, and forming a magnetic tunneling junction (MTJ) on the first metal interconnection.

### BACKGROUND OF THE INVENTION

### 1. Field of the Invention

The invention relates to a semiconductor device, and more particularly to a magnetoresistive random access memory (MRAM).

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of providing a substrate having a MRAM region and a logic region, forming a first inter-metal dielectric (IMD) layer on the substrate, forming a metal nitride layer on the first IMD layer, using a first patterned mask to remove the metal nitride layer on the logic region, using a second patterned mask to remove the metal nitride layer on the MRAM region, using a third patterned mask to remove the first IMD layer on the MRAM region and the logic region, forming a first metal interconnection on the MRAM region and a second metal interconnection on the logic region, and forming a magnetic tunneling junction (MTJ) on the first metal interconnection.

According to another aspect of the present invention, a magnetoresistive random access memory (MRAM) device includes a substrate having a MRAM region and a logic region, a first inter-metal dielectric (IMD) layer on the substrate, a first metal interconnection in the first IMD layer on the MRAM, a second metal interconnection in the first IMD layer on the logic region, and a magnetic tunneling junction (MTJ) on the first metal interconnection. Preferably, the first metal interconnection includes a first via conductor, and the second metal interconnection includes a second via conductor and a trench conductor on the second via conductor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-13 illustrate a method for fabricating a MRAM device according to an embodiment of the present invention.

### DETAILED DESCRIPTION

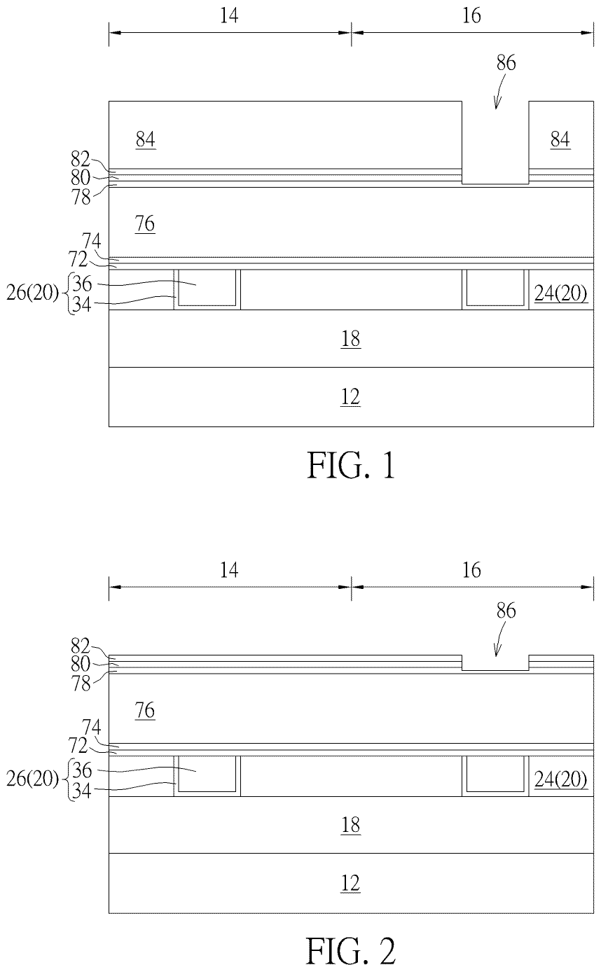

Referring to FIGS. 1-13, FIGS. 1-13 illustrate a method for fabricating a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 16 are defined on the substrate 12.

Active devices such as metal-oxide semiconductor (MOS) transistors, passive devices, conductive layers, and interlayer dielectric (ILD) layer 18 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 18 could be formed on the substrate 12 to cover the MOS transistors, and a plurality of contact plugs could be formed in the ILD layer 18 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 20 are formed on the ILD layer 18 on the MRAM region 14 and the edge region 16 to electrically connect the aforementioned contact plugs, in which the metal interconnect structure 20 includes an inter-metal dielectric (IMD) layer 24 and metal interconnections 26 embedded in the IMD layer 24. In this embodiment, each of the metal interconnections 26 from the metal interconnect structure 20 preferably includes a trench conductor and each of the metal interconnections 26 could be embedded within the IMD layer 24 according to a single damascene process or dual damascene process. For instance, each of the metal interconnections 26 could further includes a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 are preferably made of copper and the IMD layer 24 is made of silicon oxide such as tetraethyl orthosilicate (TEOS).

Next, a stop layer 72, another stop layer 74, an IMD layer 76, a hard mask 78, a metal nitride layer 80, a cap layer 82, and a patterned mask 84 are formed on the IMD layer 24, in which the patterned mask 84 includes an opening 86 exposing the surface of the cap layer 82 on the logic region 16. In this embodiment, the stop layer 72 preferably includes silicon carbon nitride (SiCN), the stop layer 74 includes TEOS, the IMD layer 76 includes an ultra low-k (ULK) dielectric layer including but not limited to for example porous material or silicon oxycarbide (SiOC) or SiOCH, the hard mask 78 includes silicon oxynitride (SiON), the metal nitride layer 80 includes titanium nitride (TiN), the cap layer 82 includes silicon oxide, and the patterned mask 84 includes a patterned resist.

Next, an etching process is conducted by using the patterned mask 84 as mask to remove part of the cap layer 82, part of the metal nitride layer 80, and/or part of the hard mask 78 on the logic region 16. Preferably, after part of the hard mask 78 is removed by the patterned mask 84, it would be desirable to expose the surface of the IMD layer 76 underneath or not exposing the surface of the IMD layer 76 such that the opening 86 still exposes the surface of the remaining hard mask 78, which are all within the scope of the present invention.

Next, as shown in FIG. 3, another patterned mask 88 is formed on the MRAM region 14 and logic region 16, in which the patterned mask 88 includes an opening 90 exposing the surface of the cap layer 82 on the MRAM region 14 and the width of the opening 90 of the patterned mask 88 formed at this stage is less than the width of the opening 86 from the patterned mask 84. Next, an etching process is conducted by using the patterned mask 88 as mask to remove part of the cap layer 82, part of the metal nitride layer 80, and part of the hard mask 78 on the MRAM region 14. Similar to the aforementioned approach for removing part of the hard mask 78 on the logic region 16, after part of the hard mask 78 on the MRAM region 14 is removed by the patterned mask 88, it would be desirable to expose the surface of the IMD layer 76 underneath or not exposing the surface of the IMD layer 76 such that the opening 90 still exposes the surface of the remaining hard mask 78, which are all within the scope of the present invention.

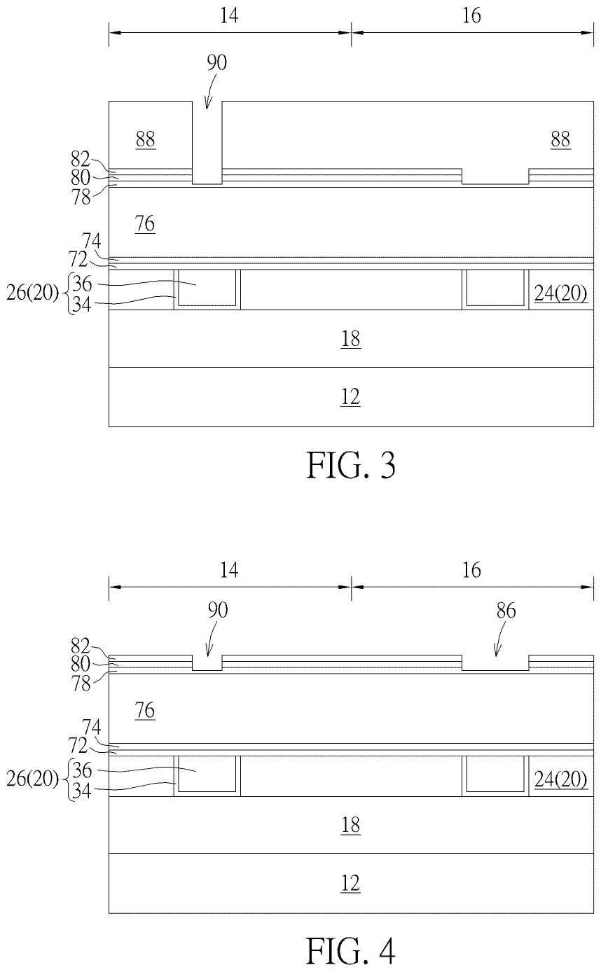

Next, as shown in FIG. 4, the patterned mask 88 is then stripped to expose the cap layer on the MRAM region 14 and logic region 16. It should be noted that an opening 90 and another opening 86 are formed in the patterned cap layer 82, patterned metal nitride layer 80, and patterned hard mask 78 on the MRAM region 14 and logic region 16 respectively at this stage, in which the width of the opening 90 on the MRAM region 14 is less than the width of the opening 86 on the logic region 16.

Next, as shown in FIG. 5, another patterned mask 92 such as patterned resist is formed on the MRAM region 14 and logic region 16, in which the patterned mask 92 includes an opening 94 exposing the hard mask 78 on the MRAM region 14 and an opening 96 exposing the hard mask 78 on the logic region 16, the width of the opening 94 on the MRAM region 14 is equal to the width of the opening 96 on the logic region 16, and the width of each of the openings 94, 96 from the patterned mask 92 is substantially equal to the width of the opening 90 on the MRAM region 14 in FIG. 4.

Next, an etching process is conducted by using the patterned mask 92 as mask to remove part of the hard mask 78, part of the IMD layer 76, and part of the stop layer 74 on the MRAM region 14 and logic region 16 at the same time so that the opening 94, 96 on each region is extended downward to form via openings 98, 100 exposing the surface of the stop layer 72 respectively.

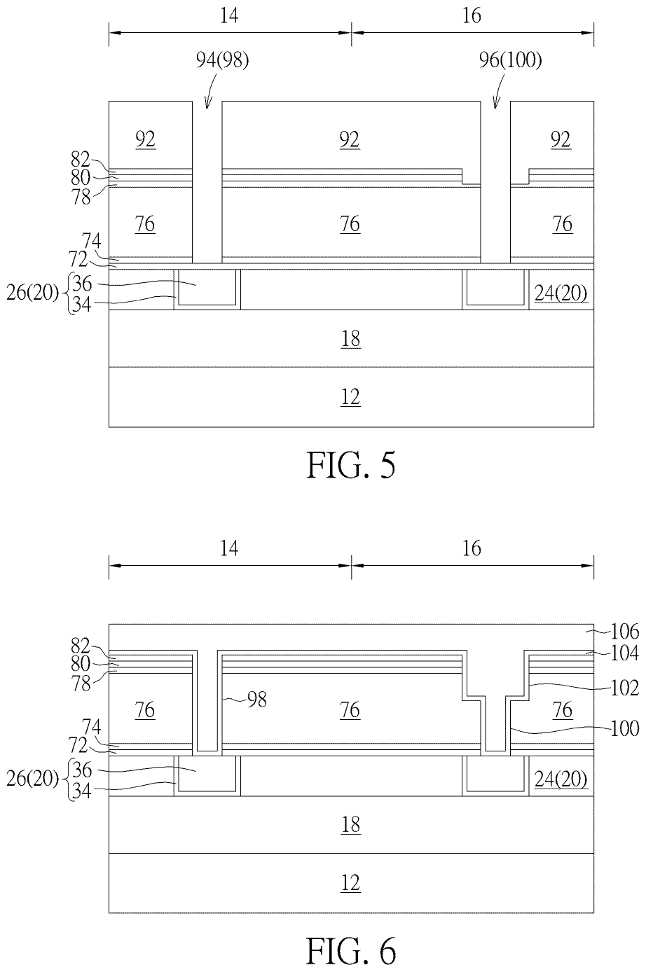

Next, as shown in FIG. 6, the patterned mask 92 is stripped, and then an etching process is conducted by using the patterned cap layer 82 as mask to remove part of the stop layer 72 at the bottom of the via opening 98 on the MRAM region 14 and part of the hard mask 78, part of the IMD layer 76, and part of the stop layer 72 not covered by the cap layer 82 on the logic region 16 so that the top portion of the via opening 100 on the logic region 16 is expanded outward to form a trench opening 102 and at the same time exposing the metal interconnections 26 directly under the via opening 98, 100 on the MRAM region 14 and logic region 16.

Next, metal or conductive materials are deposited into the via openings 98, 100 and trench opening 102. For instance, a barrier layer 104 selected from the group consisting of titanium (Ti), titanium nitride (TiN), tantalum (Ta), and tantalum nitride (TaN) and metal layer 106 selected from the group consisting of tungsten (W), copper (Cu), aluminum (Al), titanium aluminide (TiAl), and cobalt tungsten phosphide (CoWP) could be deposited into the via openings 98, 100 and trench opening 102.

Next, as shown in FIG. 7, a planarizing process such as chemical mechanical polishing (CMP) process could be conducted to remove part of the metal layer 106, part of the barrier layer 104, all the cap layer 82, all the metal nitride layer 80, and all the hard mask 78 for forming metal interconnections 108 electrically connecting the metal interconnections 26 underneath. Preferably, the metal interconnection 108 on the MRAM region 14 includes a via conductor 110 while the metal interconnection 108 on the logic region 16 includes a via conductor 112 and a trench conductor 114.

Next, another metal interconnect structure 22 is formed on the metal interconnections 108 and IMD layer 76, in which the metal interconnect structure 22 includes a stop layer 28, an IMD layer 30, and a metal interconnection 32 embedded in the stop layer 28 and IMD layer 30. It should be noted that even though the width of the bottom surface and/or top surface of the metal interconnection 32 is slightly greater than the width of the bottom surface and/or top surface of the metal interconnection 108 or via conductor 110 underneath, according to other embodiment of the present invention, the bottom surface and top surface of the metal interconnection 32 and the via conductor 110 underneath could also have same or different widths, which is also within the scope of the present invention.

Similar to the via conductor 110 formed on the MRAM region 14, the metal interconnection 32 formed directly on top of the via conductor 110 also includes a via conductor and the metal interconnection 32 could be embedded within the IMD layer 30 and/or stop layer 28 according to a single damascene process or dual damascene process. For instance, the metal interconnection 32 could further includes a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In contrast to the metal layer 36 in the IMD layer 26 includes copper, the metal layer 36 from the metal interconnection 32 at this stage preferably includes tungsten (W), the IMD layer 30 could include silicon oxide such as tetraethyl orthosilicate (TEOS), and the stop layer 28 could include nitrogen doped carbide (NDC), silicon nitride (SiN), or silicon carbon nitride (SiCN).

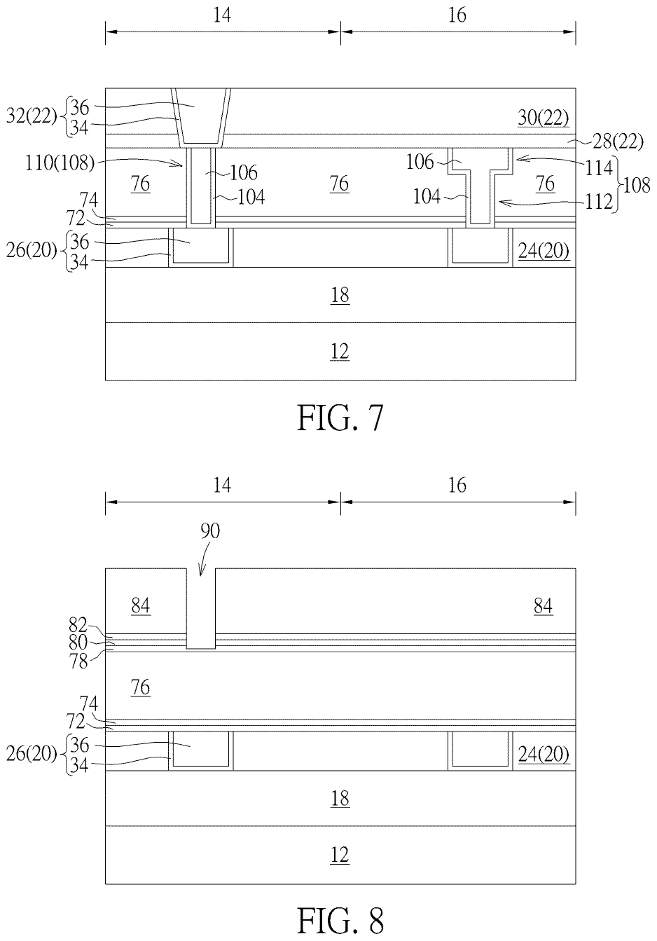

Referring to FIGS. 8-9, FIGS. 8-9 illustrate a method for fabricating a MRAM device according to an embodiment of the present invention. As shown in FIG. 8, in contrast to the embodiment shown in FIGS. 1-3 of first using the patterned mask 84 to remove part of the cap layer 82, part of the metal nitride layer 80, and part of the hard mask 78 on the logic region 16 and then using another patterned mask 88 to remove part of the cap layer 82, part of the metal nitride layer 80, and part of the hard mask 78 on the MRAM region 14, it would also be desirable to reverse the aforementioned order by first using the patterned mask 84 to remove part of the cap layer 82, part of the metal nitride layer 80, and part of the hard mask 78 on the MRAM region 14 and then using another patterned mask 88 to remove part of the cap layer 82, part of the metal nitride layer 80, and part of the hard mask 78 on the logic region 16.

For instance, as shown in FIG. 8, a patterned mask 84 is formed on the IMD layer 76, in which the patterned mask 84 includes an opening 90 exposing the surface of the cap layer 82 on the MRAM region 14. Next, an etching process is conducted by using the patterned mask 84 as mask to remove part of the cap layer 82, part of the metal nitride layer 80, and part of the hard mask 78 on the MRAM region 14.

Next, as shown in FIG. 9, after stripping the patterned mask 84, another patterned mask 88 is formed on the MRAM region 14 and logic region 16, in which the patterned mask 88 includes an opening 86 exposing the surface of the cap layer 82 on the logic region 16 and the width of the opening 86 in the patterned mask 88 is greater than the width of the opening 90 in the previous patterned mask 90. Next, an etching process is conducted by using the patterned mask 88 as mask to remove part of the cap layer 82, part of the metal nitride layer 80, and part of the hard mask 78 on the logic region 16.

Next, processes conducted in FIGS. 4-7 could be carried out by removing the patterned mask 88, using another patterned mask 92 to remove part of the hard mask 78, part of the IMD layer 76, and part of the stop layer 74 on the MRAM region 14 and logic region 16 for forming via openings 98, 100, removing the patterned mask 92, deposing conductive materials including a barrier layer 104 and metal layer 106 into the via openings 98, 100 along with a planarizing process for forming metal interconnections 108 on the MRAM region 14 and logic region 16, in which the metal interconnection 108 on the MRAM region 14 includes a via conductor 110 and the metal interconnection 108 on the logic region 16 includes a via conductor 112 and a trench conductor 114. Next, another metal interconnect structure 22 is formed on the metal interconnections 108 and IMD layer 76, in which the metal interconnect structure 22 includes a metal interconnection 32 made of via conductor disposed directly on top of the via conductor 110.

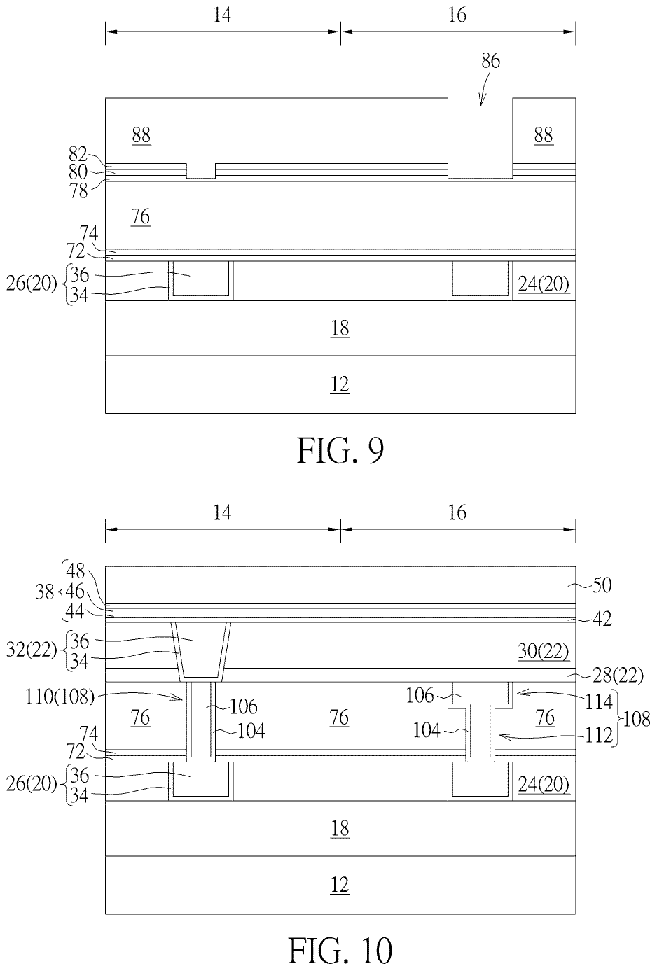

Next, as shown in FIG. 10, a bottom electrode 42, a MTJ stack 38 or stack structure, a top electrode 50, and a patterned mask (not shown) are formed on the metal interconnect structure 22. In this embodiment, the formation of the MTJ stack 38 could be accomplished by sequentially depositing a pinned layer 44, a barrier layer 46, and a free layer 48 on the bottom electrode 42. In this embodiment, the bottom electrode 42 and the top electrode 50 are preferably made of conductive material including but not limited to for example Ta, Pt, Cu, Au, Al, or combination thereof. The pinned layer 44 could be made of ferromagnetic material including but not limited to for example iron, cobalt, nickel, or alloys thereof such as cobalt-iron-boron (CoFeB) or cobalt-iron (CoFe). Moreover, the pinned layer 44 could also be made of antiferromagnetic (AFM) material including but not limited to for example ferromanganese (FeMn), platinum manganese (PtMn), iridium manganese (IrMn), nickel oxide (NiO), or combination thereof, in which the pinned layer 44 is formed to fix or limit the direction of magnetic moment of adjacent layers. The barrier layer 46 could be made of insulating material including but not limited to for example oxides such as aluminum oxide (AlOₓ) or magnesium oxide (MgO). The free layer 48 could be made of ferromagnetic material including but not limited to for example iron, cobalt, nickel, or alloys thereof such as cobalt-iron-boron (CoFeB), in which the magnetized direction of the free layer 48 could be altered freely depending on the influence of outside magnetic field.

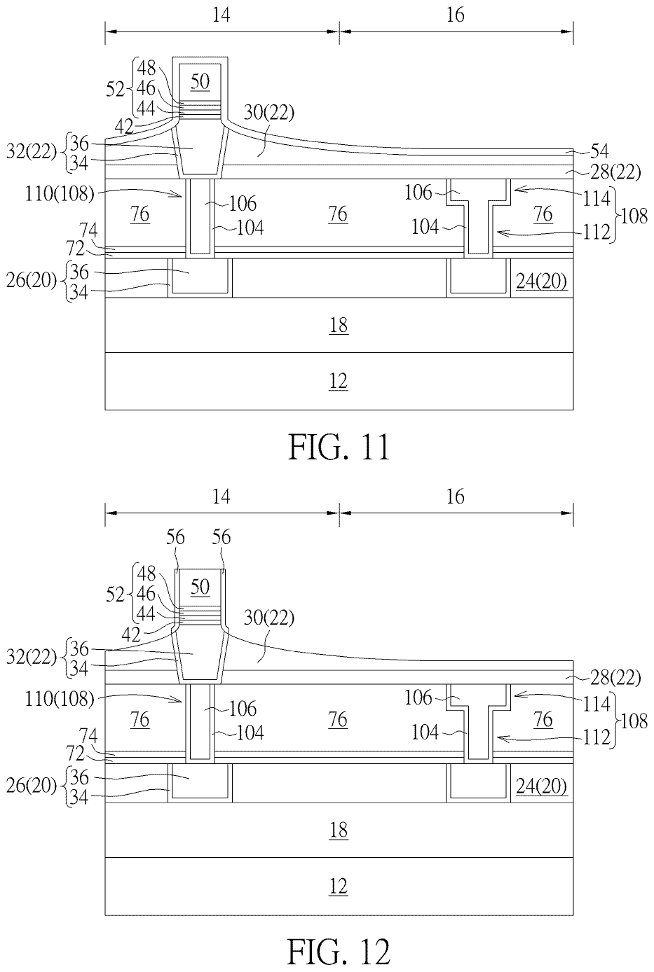

Next, as shown in FIG. 11, one or more etching process is conducted by using the patterned mask as mask to remove part of the top electrode 50, part of the MTJ stack 38, part of the bottom electrode 42, and part of the IMD layer 30 to form a MTJ 52 on the MRAM region 14. It should be noted that a reactive ion etching (RIE) and/or an ion beam etching (IBE) process is conducted to remove the top electrode 50, MTJ stack 38, bottom electrode 42, and the IMD layer 30 in this embodiment for forming the MTJ 52. Due to the characteristics of the IBE process, the top surface of the remaining IMD layer 30 is slightly lower than the top surface of the metal interconnections 32 after the IBE process and the top surface of the IMD layer 30 also reveals a curve or an arc. It should also be noted that as the IBE process is conducted to remove part of the IMD layer 30, part of the metal interconnection 32 is removed at the same time to form inclined sidewalls on the surface of the metal interconnection 32 immediately adjacent to the MTJ 52.

Next, a cap layer 54 is formed on the MTJ 52 while covering the surface of the IMD layer 30. In this embodiment, the cap layer 54 preferably includes silicon nitride, but could also include other dielectric material including but not limited to for example silicon oxide, silicon oxynitride (SiON), or silicon carbon nitride (SiCN).

Next, as shown in FIG. 12, an etching process is conducted to remove part of the cap layer 54 to form a spacer 56 around the MTJ 52 while covering and directly contacting the inclined sidewalls of the metal interconnection 32.

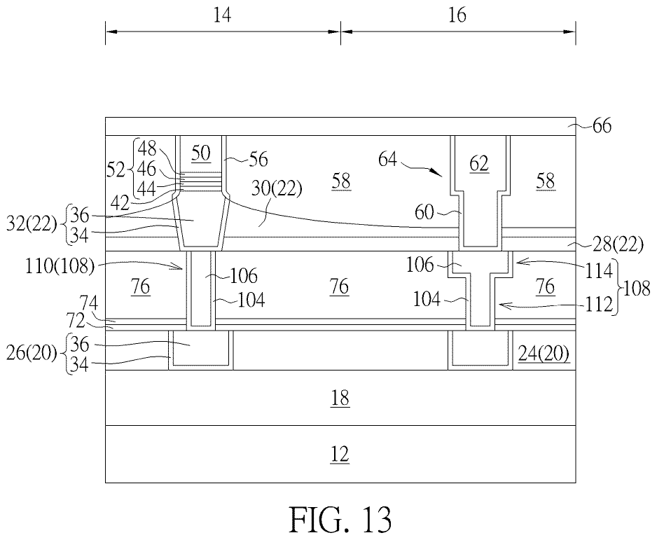

Next, as shown in FIG. 13, another IMD layer 58 is formed on the MRAM region 14 and logic region 16, and a planarizing process such as CMP is conducted to remove part of the IMD layer 58 so that the top surface of the IMD layer 58 is even with the top surface of the top electrode 50. Next, a pattern transfer or dual damascene process is conducted by using a patterned mask (not shown) to remove part of the IMD layer 58 on the logic region 16 to form a contact hole (not shown) exposing the metal interconnection 108 underneath and conductive materials are deposited into the contact hole afterwards. For instance, a barrier layer 60 selected from the group consisting of titanium (Ti), titanium nitride (TiN), tantalum (Ta), and tantalum nitride (TaN) and metal layer 62 selected from the group consisting of tungsten (W), copper (Cu), aluminum (Al), titanium aluminide (TiAl), and cobalt tungsten phosphide (CoWP) could be deposited into the contact hole, and a planarizing process such as CMP could be conducted to remove part of the conductive materials including the aforementioned barrier layer 60 and metal layer 62 to form a metal interconnection 64 in the contact hole electrically connecting the metal interconnection 108. Similar to the metal interconnection 108, the metal interconnection 64 also includes a via conductor and a trench conductor. Next, a stop layer 66 is formed on the IMD layer 58 and metal interconnection 64, in which the stop layer 66 could include silicon oxide, silicon nitride, or SiCN.

Overall, the present invention preferably forms an additional level of metal interconnections 108 between the metal interconnection 32 directly under a MTJ 52 and a lower level metal interconnection 26 on the MRAM region 14 and logic region 16, in which metal interconnections 32 and 108 between the metal interconnection 26 and MTJ 52 on the MRAM region 14 are preferably via conductors while the same level metal interconnection 108 on the logic region 16 is made of a combination of via conductor 112 and trench conductor 114. According to a preferred embodiment of the present invention, the above design could improve issues such as excessive IMD layer loading caused by IBE process and significant height difference between MRAM region and logic region such that there is an urgent need for lowering the height of MTJ as semiconductor process advances from 22 nm node into 14 nm node.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
providing a substrate having a MRAM region and a logic region;
forming a first inter-metal dielectric (IMD) layer on the substrate;
forming a metal nitride layer on the first IMD layer;
using a first patterned mask to remove the metal nitride layer on the logic region;
using a second patterned mask to remove the metal nitride layer on the MRAM region;
using a third patterned mask to remove the first IMD layer on the MRAM region and the logic region;
forming a first metal interconnection on the MRAM region and a second metal interconnection on the logic region; and
forming a magnetic tunneling junction (MTJ) on the first metal interconnection.

2. The method of claim 1, further comprising:
using the third patterned mask to remove the first IMD layer for forming a first via opening on the MRAM region and a second via opening on the logic region;
removing part of the first IMD layer on the logic region for forming a trench opening;
forming a metal layer in the first via opening, the second via opening, and the trench opening;
planarizing the metal layer for forming the first metal interconnection on the MRAM region and the second metal interconnection on the logic region.

3. The method of claim 2, wherein the first metal interconnection comprises a via conductor.

4. The method of claim 2, wherein the second metal interconnection comprises:
a via conductor; and
a trench conductor on the via conductor.

5. The method of claim 1, further comprising:
using the second patterned mask to remove the metal nitride layer on the MRAM region after using the first patterned mask to remove the metal nitride layer on the logic region.

6. The method of claim 1, further comprising:
using the first patterned mask to remove the metal nitride layer on the logic region after using the second patterned mask to remove the metal nitride layer on the MRAM region.

7. The method of claim 1, further comprising:
forming a second IMD layer on the first IMD layer;
forming a third metal interconnection on the first metal interconnection; and
forming the MTJ on the third metal interconnection.

8. The method of claim 7, wherein the third metal interconnection comprises a via conductor.

9. The method of claim 1, wherein the metal nitride layer comprises titanium nitride (TiN).

10. A magnetoresistive random access memory (MRAM) device, comprising:
a substrate having a MRAM region and a logic region;
a first inter-metal dielectric (IMD) layer on the substrate;
a first metal interconnection in the first IMD layer on the MRAM, wherein the first metal interconnection comprises a first via conductor;
a second metal interconnection in the first IMD layer on the logic region, wherein the second metal interconnection comprises:
a second via conductor;
a trench conductor on the second via conductor; and
a magnetic tunneling junction (MTJ) on the first metal interconnection.

11. The MRAM device of claim 10, further comprising:
a second IMD layer on the first IMD layer;
a third metal interconnection on the first metal interconnection; and
the MTJ on the third metal interconnection.

12. The MRAM device of claim 11, wherein the third metal interconnection comprises a third via conductor.

13. The MRAM device of claim 11, further comprising:
a third IMD layer on the second IMD layer and around the MTJ; and
a fourth metal interconnection on the second metal interconnection.

14. The MRAM device of claim 13, wherein the fourth metal interconnection comprises:
a fourth via conductor; and
a second trench conductor on the fourth via conductor.

15. The MRAM device of claim 13, wherein the bottom surfaces of the third metal interconnection and the fourth metal interconnection are coplanar.

16. The MRAM device of claim 10, wherein top surfaces of the first metal interconnection and the second metal interconnection are coplanar.
